(19) United States
(12) Patent Application Publication
(10) Pub. No.: US 2026/0370202 A1
(43) Pub. Date: Nov. 19, 2026

(54) VARIABLE GAIN AMPLIFIER CAPABLE OF NOISE CANCELLATION AND OPERATION METHOD THEREOF

(71) Applicant: THE INDUSTRY & ACADEMIC COOPERATION IN CHUNGNAM NATIONAL UNIVESITY (IAC), Daejeon (KR)

(72) Inventors: Junghwan HAN, Daejeon (KR); Segyeong KIM, Chungcheongnam-do (KR); Eunsoo KIM, Daejeon (KR)

(21) Appl. No.: 19/135,387

(22) PCT Filed: Dec. 7, 2023
(86) PCT No.: PCT/KR2023/020138

§ 371 Date: Jun. 4, 2025

(30) Foreign Application Priority Data
Oct. 11, 2023 (KR) 10-2023-0134977

(51) Int. Cl. H03G 3/30; H03F 1/26; H03F 3/193

(52) U.S. Cl. CPC H03G 3/3036; H03F 1/26; H03F 3/193; H03F 2200/372; H03F 2200/451

(57) ABSTRACT

Disclosed is a noise-cancelling variable-gain amplifier. The variable-gain amplifier includes a main amplification part, a current steering part, and a load coupling part. The main amplification part includes a first transistor in which a high-frequency signal is input to a control terminal, and a second transistor connected in series with the first transistor, thereby amplifying and outputting an input high-frequency signal. The current steering part includes a third transistor connected to a contact point where the first transistor and the second transistor are connected to each other, thereby controlling a gain of the main amplification part. The load coupling part couples the main amplification part and the current steering part using a transformer. According to the present disclosure, the noise performance of the variable-gain amplifier can be improved by implementing additional noise cancellation in low gain operation without increasing additional space or power through coupling using a load transformer.

### STATEMENT REGARDING GOVERNMENT SPONSORED RESEARCH OR DEVELOPMENT

This work was supported in part by the Next Generation Intelligence Semiconductor Foundation Program (20025736, Development of MICS SoC and platform for in-vivo implantable electroceutical device) funded by the Ministry of Trade, Industry & Energy (MOTIE, Korea) under Grant 20025736 and in part by Basic Science Research Program through the National Research Foundation of Korea (NRF) funded by the Ministry of Education (MOE) under Grant RS-2023-00246633.

### TECHNICAL FIELD

The present disclosure relates to a noise-cancelling variable-gain amplifier and an operating method thereof, and more specifically, to a variable-gain amplifier capable of improving noise performance even in low gain operation using a load transformer, and an operating method thereof.

### BACKGROUND ART

Beamforming technology used in 5G mobile communication has been widely adopted in a millimeter-wave 5G NR (New Radio) transceiver to achieve improved data throughput and signal directivity through a phased-array structure and to overcome high signal path loss. A phased-array transceiver system is composed of several front-ends including a variable-gain amplifier (VGA), a low-noise amplifier (LNA), and a phase shifter (PS).

In practice, there is a growing demand for designs that reduce size and cost through integration between stages with similar roles within a single front-end for a low-cost, high-efficiency transceiver design in the phased-array structure that requires a large number of beams and elements. However, a conventional variable gain amplifier exhibits a characteristic in which noise performance deteriorates proportionally as the gain decreases. Therefore, conventionally, a separate low-noise amplifier is essentially placed at a front end in the phased-array structure based on the Friis equation to alleviate the overall system noise performance deterioration at low gain.

A variable gain amplifier (VGA) is used to reduce gain error due to phase change for each phased array path and to reduce side lobes through fine gain adjustment for each beam. Conventional methods for controlling the gain of the variable gain amplifier include a method of controlling the gain of the amplifier by varying load impedance using a control signal, a method of controlling the entire amplifier gain by applying a separate variable attenuator between amplifier stages, and a method of controlling the gain by controlling the amount of current flowing to the load using a current-steering stage.

The method of varying the load impedance or applying the separate variable attenuator has been widely applied because it can obtain fine gain adjustment and a relatively large gain control range (GCR). However, when the gain is lowered, the noise performance and noise figure (NF) deteriorate according to the Friis equation, requiring more power consumption from the low-noise amplifier in a previous stage, and the noise performance is further degraded by the parasitic components of various switches added for variation. This ultimately degrades the signal-to-noise ratio (SNR) characteristics of an entire phased array receiver.

The current-steering technique has the advantage of maintaining a constant input impedance because the magnitude of the bias current flowing through a common-source (CS) amplifier in a cascode structure does not change. Patent Publication No. 10-2022-0091178, published on Jun. 30, 2023, relates to “Low-noise amplifier and operating method thereof,” and discloses a low-noise amplifier including an amplification part including a first transistor and a second transistor connected to each other in a cascode structure, and a gain control part connected between a first contact point at which the first transistor and the second transistor are connected to each other and a power supply voltage. The amplification part amplifies a first signal input to a control terminal of the first transistor, and the gain control part adjusts the gain of the amplification part.

However, this also has the disadvantage that as the gain decreases, the overall noise performance decreases significantly due to the additional noise contribution of a cascode elements used for current steering. A novel variable gain amplifier structure is required that has a sufficient gain control range to compensate for the above problem while minimizing noise performance degradation due to gain reduction.

### PRIOR ART DOCUMENT

### (Patent Document) KR 10-2022-0091178 A (2022.06.30.)

### DETAILED DESCRIPTION OF INVENTION

### Technical Problems

According to one embodiment of the present disclosure, the present disclosure provides a novel variable-gain amplifier structure and method with improved noise performance for a variable-gain amplifier (VGA), primarily used for signal size control in a wireless communication system.

According to one embodiment of the present disclosure, the present disclosure provides a novel variable-gain low noise amplifier structure and method to which a transformer-based noise cancelling technique is applied.

According to one embodiment of the present disclosure, the present disclosure provides a novel variable-gain low noise amplifier structure and method with improved noise performance without additional power consumption in a phased array system.

The objectives to be achieved by the present disclosure are not limited to the above-mentioned objectives, and other objectives which are not mentioned will be clearly understood by those skilled in the art from the following description.

### Technical Solution

According to an aspect of the present disclosure, a noise-cancelling variable-gain amplifier includes a main amplification part, a current steering part, and a load coupling part.

The main amplification part includes a first transistor in which a high-frequency signal is input to a signal input terminal, and a second transistor connected in series with the first transistor, thereby amplifying and outputting an input high-frequency signal.

The current steering part includes a third transistor cascode-connected to the first transistor in parallel with the second transistor at a contact point where the first transistor and the second transistor are connected to each other, thereby controlling a gain of the main amplification part.

The load coupling part is connected to the main amplification part and the current steering part, respectively, to couple a high-frequency signal of the main amplification part and a high-frequency signal of the current steering part.

According to a further aspect, the load coupling part includes a transformer configured so that a primary coil is connected between a power supply voltage and the main amplification part, and a secondary coil is connected between the power supply voltage and the current steering part.

According to a further aspect, the load coupling part includes a first inductor connected between the second transistor and the power supply voltage, and a second inductor connected between the third transistor and the power supply voltage. The first inductor is magnetically coupled to the second inductor.

According to a further aspect, the load coupling part further includes a capacitor connected in parallel with the first inductor between the second transistor and the power supply voltage.

According to a further aspect, the third transistor includes a plurality of transistors connected in parallel with each other, each of the transistors being turned on or off in response to a control signal.

According to another aspect of the present disclosure, a method of operating a noise-cancelling variable-gain amplifier includes the steps of inputting a high-frequency signal to a gate terminal that is a signal input terminal of a first transistor, amplifying the input high-frequency RF signal to a current signal, using the first transistor, operating a third transistor cascode-connected to the first transistor in parallel with a second transistor at a contact point where the cascode-connected first transistor and second transistor are connected to each other, in response to a control signal, coupling a high-frequency signal flowing through the second transistor and a high-frequency signal flowing through the third transistor, and outputting an amplified signal from the second transistor.

According to a further aspect, the method further includes a step of controlling a current flowing through the second transistor according to operation of the third transistor.

According to a further aspect, in the step of coupling the high-frequency signals, a coupling amount is determined by a coupling coefficient between a primary coil of a transformer connected to the second transistor and a secondary coil of the transformer connected to the third transistor.

According to a further aspect, the method further includes a step in which a signal flowing out of the primary coil and a signal flowing into the secondary coil via the third transistor are coupled to each other and canceled out, for a noise signal generated from the second transistor.

According to a further aspect, the method further includes a step in which a signal flowing into the primary coil via the second transistor and a signal flowing into the secondary coil are coupled to each other and canceled out, for a noise signal generated from the third transistor.

### Effect of Invention

A noise-cancelling variable-gain amplifier and an operating method thereof according to the present disclosure provide a novel gain control method using coupling between in-phase signal currents by using a load transformer with a coupling coefficient smaller than 1.

Moreover, a variable-gain amplifier according to the present disclosure can adjust a gain control range by appropriately selecting a coupling coefficient of a load transformer smaller than 1. By partially cancelling the noise of cascode elements of a main amplification part and a current steering part through a load transformer, the problem of rapid increase in noise due to gain attenuation in a conventional variable-gain amplifier can be alleviated.

Further, a variable-gain amplifier according to the present disclosure can improve performance without wasting additional space or power by replacing an existing load inductor with a transformer. This can be applied to the variable-gain amplifier using an NMOS current steering structure, and can be effectively used in a phased array system that requires a gain adjustment interval and a noise increase rate to be adjusted depending on the application.

A variable-gain low-noise amplifier according to the present disclosure can be usefully applied to the design of a low-cost and low-power transceiver in a phased array system with multiple front-ends or MIMO (multiple-input multiple-output) communication without applying a separate additional low-noise amplifier (LNA).

### BRIEF DESCRIPTION OF THE DRAWING

FIG. 1 is a schematic view showing the configuration of a noise-cancelling variable-gain amplifier according to an embodiment.

FIG. 2 is a circuit diagram showing the main configuration of the noise-cancelling variable-gain amplifier according to an embodiment.

FIG. 3 is a circuit diagram explaining the operation of the noise-cancelling variable-gain amplifier according to an embodiment.

FIG. 4 is an equivalent circuit diagram for finding an output impedance of the noise-cancelling variable-gain amplifier according to an embodiment.

FIG. 5 is a circuit diagram showing a noise cancelling mechanism for channel noise contributed from a cascode element (second transistor) in a main amplification part of the noise-cancelling variable-gain amplifier according to an embodiment.

FIG. 6 is a circuit diagram showing a noise cancelling mechanism for channel noise contributed from a gain control element (third transistor) in a current steering part of the noise-cancelling variable-gain amplifier according to an embodiment.

FIGS. 7A and 7B are graphs showing the results of simulating the voltage gain and noise factor of the noise-cancelling variable-gain amplifier according to an embodiment for changes in a and coupling coefficient k.

FIG. 8 is a circuit diagram showing the specific configuration of the noise-cancelling variable-gain amplifier according to an embodiment.

FIGS. 9A and 9B are graphs showing the results of simulating the voltage gain and noise factor according to changes in the value of k for the specific configuration of the noise-cancelling variable-gain amplifier according to an embodiment.

FIGS. 10A and 10B are graphs showing the results of simulating the gain and noise factor according to changes in gain control signal and frequency for the specific configuration of the noise-cancelling variable-gain amplifier according to an embodiment.

FIGS. 11A and 11B are schematic views showing the configuration of a front-end of a phased array receiver according to the prior art and a front-end of a phased array receiver using a noise-cancelling variable-gain amplifier according to an embodiment.

FIG. 12 is a flowchart schematically showing the operating method of a noise-cancelling variable-gain amplifier according to an embodiment.

### BEST MODE FOR CARRYING OUT THE INVENTION

The above and other aspects are embodied through embodiments described with reference to the accompanying drawings. Unless otherwise stated or contradictory, it is understood that the components of each embodiment can be variously combined within the embodiment or with components of other embodiments. Based on the principle that an inventor may appropriately define terms to best describe his or her own invention, the terms used in this specification and claims shall be interpreted in accordance with the meanings and concepts consistent with the description or the disclosed technical idea. As used herein, a module or part may refer to a set of program instructions stored in a memory to be executed by a computer or processor, or may be implemented using a set of electronic components or circuits, such as an ASIC or FPGA, to perform these instructions. Further, the operation of each module or part may be performed by one or more processors or devices. Since components denoted by the same or similar reference numerals perform the same or similar functions, detailed descriptions thereof may be omitted. For components with reference numerals for which descriptions are omitted, reference may be made to the previous descriptions of components having the same or similar reference numerals.

Hereinafter, preferred embodiments of the present disclosure will be described in detail with reference to the accompanying drawings.

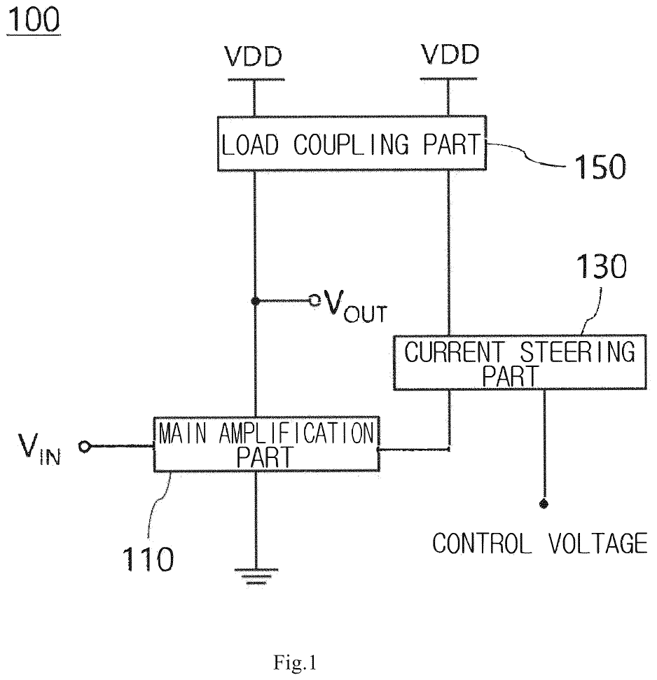

FIG. 1 is a schematic view showing the configuration of a noise-cancelling variable-gain amplifier according to an embodiment.

The noise-cancelling variable-gain amplifier 100 according to an embodiment includes a main amplification part 110, a current steering part 130, and a load coupling part 150.

The main amplification part 110 is located between a ground GND and the load coupling part 150, amplifies an input high-frequency RF (radio frequency) signal V_{IN}, and outputs the amplified high-frequency RF signal v_{OUT}. The main amplification part 110 may include one or more transistors.

The current steering part 130 is connected to the load coupling part 150 and the main amplification part 110 to control a current flowing in the main amplification part 110 in response to a control signal or control voltage. The current steering part 130 may include one and more transistors.

The load coupling part 150 is connected at one side thereof between a power supply voltage VDD and the main amplification part 110, and connected at the other side thereof between the power supply voltage VDD and the current steering part 130, thereby coupling a high-frequency signal of the main amplification part 110 and a high-frequency signal of the current steering part 130. The coupling part 150 may include one and more transformers.

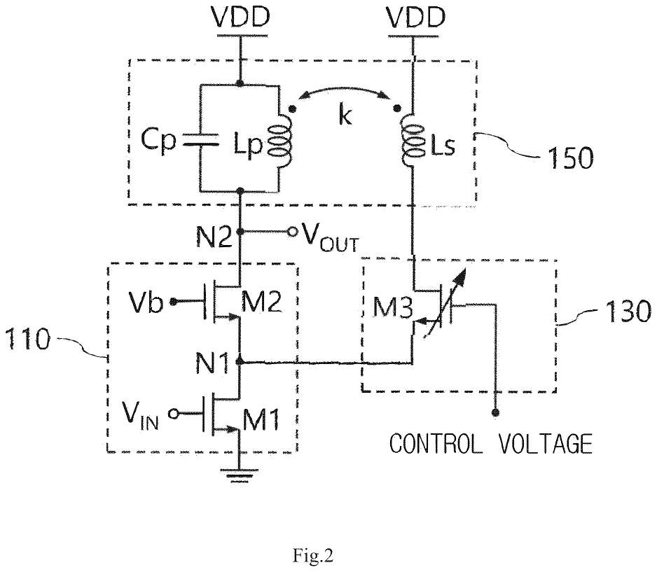

FIG. 2 is a circuit diagram showing the main configuration of the noise-cancelling variable-gain amplifier according to an embodiment.

The main amplification part 110 includes a first transistor M1, which is an input transconductance element in which the high-frequency signal v_{IN} is input to a gate terminal which is a signal input terminal, and a second transistor M2, which is a cascode element cascode-connected in series with the first transistor M1, thereby amplifying the input high-frequency signal and outputting the amplified high-frequency signal v_{OUT}.

The current steering part 130 includes a third transistor M3, which is a gain control element cascode-connected to the first transistor M1 in parallel with the second transistor M2 at a contact point N1 where the first transistor M1 and the second transistor M2 are connected to each other, thereby controlling the gain of the main amplification part 110. The operation of the third transistor M3, which is a gain control element, is controlled by a control voltage. By controlling the input impedance of the third transistor, a current i2 flowing to the second transistor and a current i3 flowing to the third transistor may be controlled.

The load coupling part 150 includes a first inductor Lp connected between the second transistor M2 and the power supply voltage, and a second inductor Ls connected between the third transistor M3 and the power supply voltage. The first inductor Lp is magnetically coupled to the second inductor Ls. The first inductor Lp is coupled to the second inductor Ls with a coupling coefficient k.

The first inductor Lp and the second inductor Ls may be configured as a single transformer with the coupling coefficient k. That is, the inductors of the load coupling part 150 may be implemented using a single transformer in which a primary coil Lp is connected between the power supply voltage VDD and the main amplification part 110, and a secondary coil Ls is connected between the power supply voltage VDD and the current steering part 130. The load coupling part 150 may couple the main amplification part 110 and the current steering part 130 by the transformer.

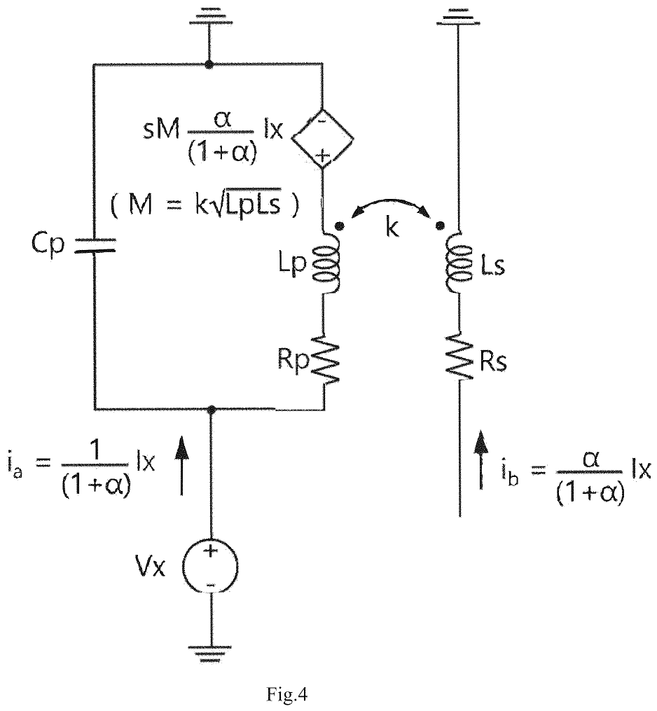

The load coupling part 150 may further include a capacitor Cp that is connected in parallel with the first inductor Lp between the second transistor M2 and the power supply voltage. It is preferable to use the first inductor Lp and capacitor Cp that satisfy Equation 3 described in FIG. 4 below so that resonance is achieved at a frequency ω0 of the input high-frequency RF signal.

The first transistor M1, the second transistor M2, and the third transistor M3 may use any known amplifying transistor, such as a bipolar transistor, but it is preferable to use a metal oxide semiconductor field effect transistor (MOSFET), which is easy to manufacture into an integrated circuit. A third transistor may be configured by connecting multiple MOSFETs in parallel, each of which is turned on and off in response to a control signal. In this case, by changing the number of transistors that are turned on among the parallel-connected MOSFETs, the size ratio α of the second transistor and the third transistor may be easily changed.

Referring to FIG. 2, all of the first transistor M1, the second transistor M2, and the third transistor M3 may be configured as NMOS. The input signal v_{IN} is input to a gate of the first transistor M1, and a source of the first transistor M1 is connected to the ground. A drain of the first transistor M1 is connected to the source of the cascoded second transistor M2 at a N1 node. A drain of the second transistor M2 is connected to the load coupling part 150 at a N2 node, and an amplified output signal v_{OUT} is output from the drain (N2 node) of the second transistor M2.

The capacitor Cp of the load coupling part 150 is connected between the power supply VDD and the drain (N2 node) of the second transistor M2, and the first inductor Lp, which is the primary coil of the transformer, is connected between the power supply VDD and the drain (N2 node) of the second transistor M2 in parallel with the capacitor Cp. The second inductor Ls, which is the secondary coil of the transformer, is connected between the power supply VDD and the drain of the third transistor M3.

A source of the third transistor M3 is connected to the N1 node to be cascode-connected to the first transistor M1. The third transistor M3 may be varied by the control signal connected to the gate. If the third transistor M3 is composed of multiple NMOSs and a bit of the control signal is assigned to the gate of each NMOS, the current flowing to the third transistor may be controlled by turning each NMOS on and off. Although FIG. 2 discloses a circuit of a variable-gain amplifier implemented using NMOS, it is also possible to implement a variable-gain amplifier using PMOS.

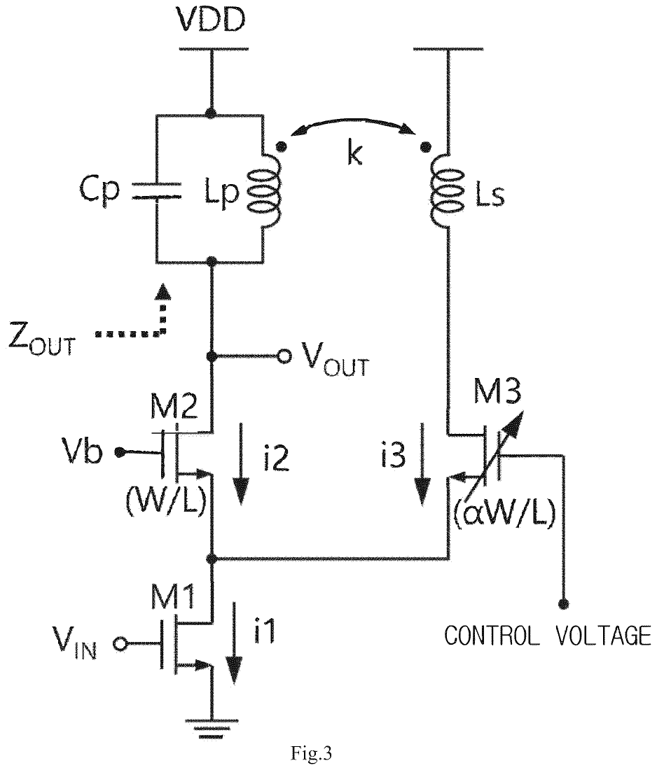

FIG. 3 is a circuit diagram explaining the operation of the noise-cancelling variable-gain amplifier according to an embodiment.

Referring to FIG. 3, the variable-gain low-noise amplifier 100 to which a transformer-based noise cancelling technique is applied, may be configured based on a cascode common-source structure that integrates the main amplification part 110 and the current steering part 130 for gain control. The variable-gain amplifier may be configured to include a transformer 150 between the main amplification part and the load of the current steering part. With this configuration, the high-frequency (radio frequency, RF) signal current flowing into the current steering part is coupled back to the main amplification part and combined with an in-phase main signal, thereby reducing amplifier gain variation and noise.

The input transconductance element M1 converts the input RF voltage signal v_{IN} into the RF current (i1=i_{RF}=gₘ₁ v_{IN}) signal. Here, g_{mX} represents the transconductance value of the transconductance element Mx. When the control voltage of the third transistor M3 is set so that the current i3 flowing in the gain control element M3 of the current steering part is α times larger than the current i2 flowing in the cascode element M2 of the main amplification part, then, since i1=i2+i3, it follows that i2=1/(1+α)·i1 and i3=α/(1+α)·i1.

When using the MOSFET, the current flowing through the element is proportional to the size of the MOSFET, so “α” represents the ratio of the size (width) (αW*L) of the gain control element M3 to the size (width) (W*L) of the cascode element M2. When the gain control element M3 of the current steering part is turned on and off so that the size of the gain control element M3 is set to be α times larger than the size of the cascode element M2 of the main amplification part, then, since i1=i_{RF}, the RF current flows to the cascode element M2 of the main amplification part by i2=1/(1+α)·i_{RF}, and flows through the gain control element M3 of the current steering part by i3=α/(1+α)·i_{RF}.

FIG. 4 is an equivalent circuit diagram for finding an output impedance of the noise-cancelling variable-gain amplifier according to an embodiment.

To determine the overall gain of the amplifier, including the transformer load coupling effect, load output impedance Z_{OUT} should be calculated by considering the current flow in both the main amplification part 110 and the current steering part 130. Referring to the equivalent circuit of FIG. 4, the output impedance Z_{OUT} may be derived by considering the RF current flowing in the main amplification part 110 and the current steering part 130 and the transformer load.

The mutual inductance M of two inductor coils with the coupling coefficient k is equal to M=k\sqrt{LₚLₛ}. To simplify the analysis, assuming that Lp=Ls and Rp=Rs, the mutual inductance M is simplified to the product kLp of the coupling coefficient k and the inductance Lp of the first inductor. Therefore, the output impedance Z_{OUT} may be obtained using the following Equation 1.

$${Z}_{OUT} ( s ) = \frac{{V}_{X}}{{I}_{X} / ( 1 + α )} = \frac{{R}_{P} + {sL}_{P} ( 1 + α K )}{1 + {sR}_{P} {C}_{P} + {s}^{2} {L}_{P} {C}_{P}} \qquad [ Equation 1 ]$$

Here, Lp is the transformer primary inductance, Ls is the transformer secondary inductance, Rp is the transformer primary parasitic series resistance, and Rs is the transformer secondary parasitic series resistance.

At the resonance frequency ω₀, when the primary inductor Lp resonates with the parallel capacitor Cp, the impedance Z_{OUT} may be obtained using the following Equation 2, assuming that Lp/RpCp»Rp in the maximum gain mode (α=0).

$${Z}_{OUT} ( {jw}_{0} ) = \frac{{L}_{P}}{{R}_{P} {C}_{P}} + α K ( \frac{{L}_{P}}{{R}_{P} {C}_{P}} - {R}_{P} ) ≅ \frac{{L}_{P}}{{R}_{P} {C}_{P}} ( 1 + α k ) \qquad [ Equation 2 ]$$

Here, the resonance frequency ω₀ may be determined using the following Equation 3.

$${w}_{0} = \sqrt{\frac{{L}_{P} - {R}_{P}^{2} {C}_{P}}{{L}_{P}^{2} {C}_{P}}} \qquad [ Equation 3 ]$$

Therefore, the final voltage gain G of the variable-gain low-noise amplifier considering a cascode stage may be obtained using the following Equation 4.

$$G = {g}_{m 1} \frac{1}{1 + α} \frac{{L}_{P}}{{R}_{P} {C}_{P}} ( 1 + α k ) = {g}_{m 1} \frac{{L}_{P}}{{R}_{P} {C}_{P}} \frac{1 + α k}{1 + α} \qquad [ Equation 4 ]$$

In Equation 4, the gain of the variable-gain low-noise amplifier changes as a increases for the case of k<1, which is a general transformer condition. That is, the smaller the coupling coefficient k, the larger the gain control range may be. Thus, the gain control range may be adjusted through transformer design.

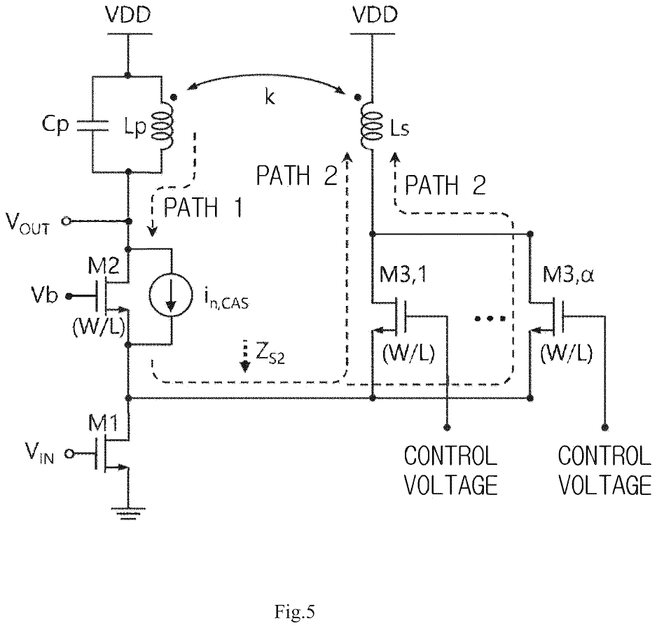

FIG. 5 is a circuit diagram showing a noise cancelling mechanism for channel noise contributed from the cascode element in the main amplification part of the noise-cancelling variable-gain amplifier according to an embodiment.

As with the above-described gain analysis, the amount of RF current flowing into the current steering stage may be adjusted by adjusting the size of the third transistor M3, which is the gain control element. Referring to FIG. 5, the current steering part 130 includes a gain control elements from M3,1 to M3,α. Each gain control element is configured to have the same size (W*L), so that the entire size of the gain control elements connected in parallel becomes αW*L. Each gain control element may control the on-off operation using a control bit signals. Here, for ease of analysis, each gain control element is assumed to have the same size (W*L). However, it may be set with different sizes, such as sizes increasing by a factor of two, if necessary.

When in the maximum gain mode (all the gain control elements M3,1-M3,α are turned off), the noise contribution from the cascode element M2 does not significantly affect the overall noise performance because of the high impedance Z_{S2} seen at the source terminal of the second transistor M2, which is the cascode element.

However, in the low gain mode, a gain control elements M3,1-M3,α are turned on for RF current steering, thereby lowering the Z_{S2} impedance. This results in a significant increase in the noise contribution of the cascode element M2 and gain control element M3 to the output. The variable-gain low-noise amplifier 100 according to an embodiment further provides noise cancelling characteristics through the transformer even in the low gain mode, thereby reducing the noise contribution of the cascode element M2, which is the second transistor, and the gain control element M3, which is the third transistor, to the output in the low gain mode.

FIG. 5 shows a state where noise current_{in,CAS} is generated by the cascode element M2 in the low gain mode. Some of the noise current_{in,CAS} appears directly to the output load via path 1. At this time, since the sizes W*L of the second transistor M2 and the third transistor M3,1 to M3,α are the same, if gₘ₂=g_{m3,1}= . . . =g_{m3,α}, then the noise current appearing through path 1 becomes α/(α+1)·i_{n,CAS}.

On the other hand, the same amount of noise current may be introduced into the secondary coil of the transformer through path 2 passing through the gain control elements M3,1-M3,α and coupled to the output in an out-phase. As a result, the variable-gain low-noise amplifier 100 according to one embodiment may partially eliminate channel noise originating from the cascode element M2 of the main amplification part.

A total noise voltage v_{n,OUT} appearing in the output through path 1 and path 2 due to the channel noise of the cascode element M2 of the main amplification part may be expressed as the following Equation 5.

$${v}_{n , OUT}^{2} {\vert}_{M 2} = \frac{{R}_{P} + {sL}_{P} ( 1 - k )}{1 + {sR}_{P} {C}_{P} + {s}^{2} {L}_{P} {C}_{P}} \frac{α}{1 + α} {i}_{n , CAS} \qquad [ Equation 5 ]$$

Assuming a sufficiently small value of k and Lp/RpCp»Rp under the resonance condition ω₀ obtained from the above Equation 3, the output noise power

$$\overline{{v}_{n , OUT}^{2}} {\vert}_{M 2}$$

provided by the cascode element M2 may be obtained by the following Equation 6.

$$\overline{{v}_{n , OUT}^{2}} {\vert}_{M 2} ≅ \frac{{{L}_{P}^{2} ( 1 - k )}^{2}}{{R}_{P}^{2} {C}_{P}^{2}} \frac{{α}^{2}}{{( 1 + α )}^{2}} \overline{{i}_{n , CAS}^{2}} \qquad [ Equation 6 ]$$

As can be seen from Equation 6 above, the output noise power from the cascode element M2 of the main amplification part decreases as k increases for a predetermined specific α value. In Equation 6, perfect noise cancellation is achieved in the case of an ideal transformer (k=1). When there is no magnetic coupling (k=0), the transformer-based noise cancellation technique is not applied, resulting in noise from the cascode element M2.

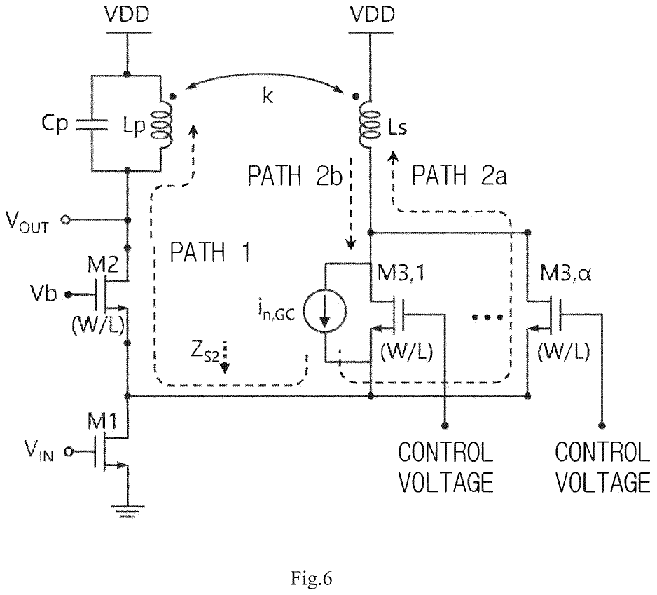

FIG. 6 is a circuit diagram showing a noise cancelling mechanism for the channel noise contributed from the gain control element in the current steering part of the noise-cancelling variable-gain amplifier according to an embodiment.

FIG. 6 shows a state in which noise current i_{n,GC} is generated in one M3,1 of the gain control elements M3,1-M3,α of the current steering part. Due to a elements (α−1 from M3 and one M2 element connected together) excluding one M3,1 of the gain control elements, a noise current of [1/(α+1)]·i_{n,GC} appears at the output through path 1.

Since the noise current passing through the secondary coil of the transformer flows into the coil via (α−1) paths (path 2a) with the magnitude of [(α−1)/(α+1)]·i_{n,GC}, and flows out of the coil via one path (path 2b) with the magnitude of [α/(α+1)]·i_{n,GC}, the noise current (path 2) flowing into the secondary coil of the transformer to be coupled to the output voltage becomes [(α−1)/(α+1)−α/(α+1)]·i_{n,GC}. Therefore, the coupled noise voltage v_{n,OUT} at the output may be obtained as shown in the following Equation 7.

$${v}_{n , OUT} {\vert}_{M 3 , 1} = \frac{{R}_{P} + {sL}_{P} ( 1 - k )}{1 + {sR}_{P} {C}_{P} + {s}^{2} {L}_{P} {C}_{P}} \frac{1}{1 + α} {i}_{n , GC} \qquad [ Equation 7 ]$$

Considering the value of α, which represents the number of gain control elements M3 that are turned on and operating, the output noise power exhibited by all the gain control elements M3,1-M3,α under the same resonant frequency ω₀ condition may be expressed as shown in the following Equation 8.

$$\overline{{v}_{n , OUT}^{2}} {\vert}_{M 3 , 1 - M 3 , α} ≅ \frac{{{L}_{P}^{2} ( 1 - k )}^{2}}{{R}_{P}^{2} {C}_{P}^{2}} \frac{α}{{( 1 + α )}^{2}} \overline{{i}_{n , CAS}^{2}} \qquad [ Equation 8 ]$$

Similar to the noise cancellation by the cascode element M2 of the main amplification part, the above Equation 8 also shows that for a predetermined specific value of α, a larger coupling coefficient k of the transformer in the low gain mode indicates a smaller noise contribution from the gain control element M3. That is, the noise of the gain control elements M3.1-M3.α of the current steering part may also be partially eliminated through the variable-gain low-noise amplifier 100 using the transformer according to one embodiment.

Assuming perfect input matching conditions, the final noise factor (NF) of the variable-gain low-noise amplifier 100 may be determined using the following Equation 9.

$$NF ≅ 1 + EF {\vert}_{M 1} + EF {\vert}_{M 2} + EF {\vert}_{M 3 , 1 - M 3 , α} ≅ 1 + \frac{4 γ}{{g}_{m 1} {R}_{S}} + \frac{4 γ {{g}_{m 2} ( 1 - k )}^{2} {α}^{2}}{{g}_{m 1}^{2} {{R}_{S} ( 1 + α k )}^{2}} + \frac{4 γ {{g}_{m 2} ( 1 - k )}^{2} α}{{g}_{m 1}^{2} {{R}_{S} ( 1 + α k )}^{2}} \qquad [ Equation 9 ]$$

Here, EF represents the noise contribution of each element as the excess noise factor of each element, and γ represents the excess noise coefficient of the element.

As can be seen from the above Equation 9, when there is no load transformer (k=0), as the number α of turned-on gain control elements increases, the noise factor by the cascode element M2 increases by α² times, and the noise factor by the gain control element M3 increases by α times, so that the performance of the noise factor NF is significantly degraded.

In contrast, it can be seen that the transformer with the coupling coefficient k added to the main amplification part 110 and the current steering part 130 alleviates the deterioration of the noise factor NF by a factor of [(1−k)/(1+αk)]².

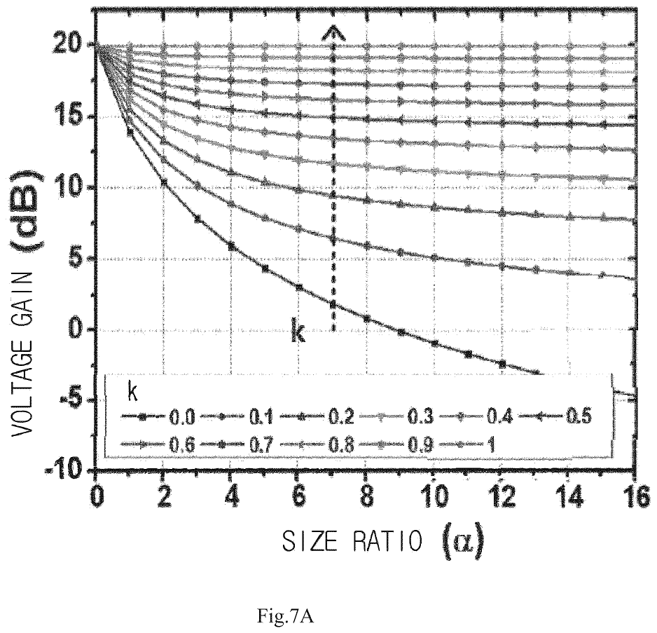

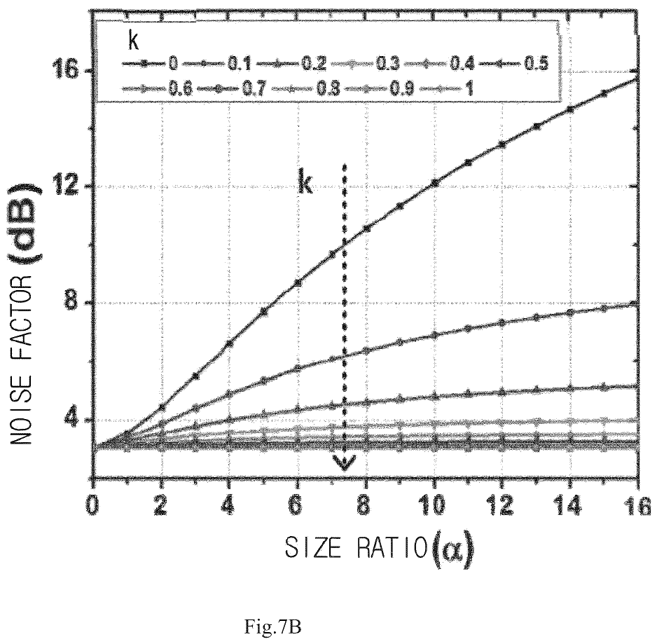

FIGS. 7A and 7B are graphs showing the results of simulating the voltage gain and noise factor of the noise-cancelling variable-gain amplifier according to an embodiment for changes in α and k.

In particular, FIG. 7A is a graph showing the result of simulating voltage gain dB for changes in α and k using the final voltage gain equation of Equation 4, and FIG. 7B is a graph showing the result of simulating the noise factor dB for changes in α and k using the final noise factor equation of Equation 9. The value of α is displayed on the horizontal axis, the graphs according to the change in the value of k are displayed in different colors, and an arrow is displayed from the graph with k=0 to the graph with k=1 (in the direction of increasing k value).

Referring to FIG. 7A, towards the right of the horizontal axis (large a value), that is, as more gain control elements are turned on, the overall gain value decreases. Further, as the value of k decreases, a smaller number of in-phase RF signals are induced from the current steering part 130 to the main amplification part 110, thereby increasing the gain control range according to the change in the value of α. On the other hand, when the value of k is large, the gain control range of the variable-gain amplifier is reduced but more precise control is possible.

Referring to FIG. 7B, it can be seen that as a increases, the noise factor NF increases, thereby degrading the performance, but as the value of k increases, the amount of increase in NF decreases due to the noise cancelling effect, so that when k=0.4 or more, the performance degradation is sufficiently alleviated even if a increases.

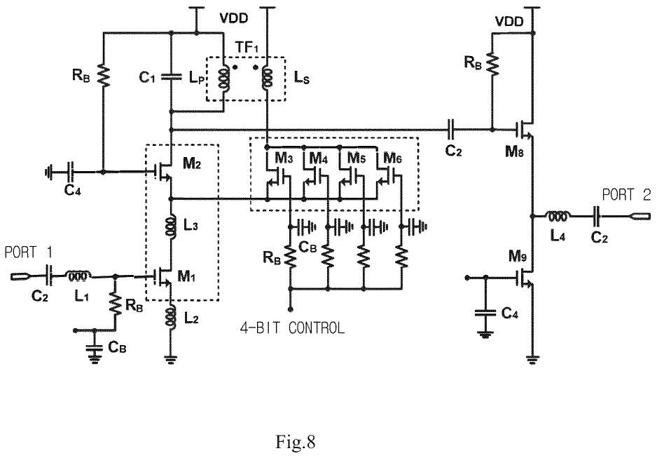

FIG. 8 is a circuit diagram showing the specific configuration of the noise-cancelling variable-gain amplifier according to an embodiment.

The variable-gain low-noise amplifier according to an embodiment is designed and simulated based on a 65 nm CMOS process. The simulation is conducted for the center frequency of 28 GHz, which is the n257 and n261 frequency bands of 5G NR FR2 (26.5 to 29.5 GHz).

Referring to FIG. 8, the variable-gain low-noise amplifier 100 is applied so that a load transformer TF1 of the load coupling part 150 is coupled to the main amplification part 110 and the current steering part 130. The input transconductance element M1 of the main amplification part 110 is configured so that a source is connected to the ground through an inductor L2 and a drain is connected to the source of the cascode element M2 through an inductor L3.

The gain control elements M3 to M6 of the current steering part are designed with binary-weighted sizes, and are adjustable through 4-bit control. In this case, the value of α may be set up to 2⁴−1=15.

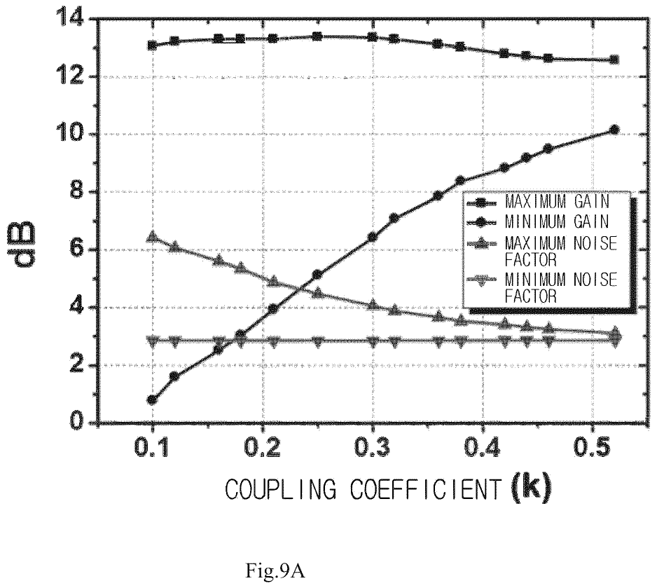

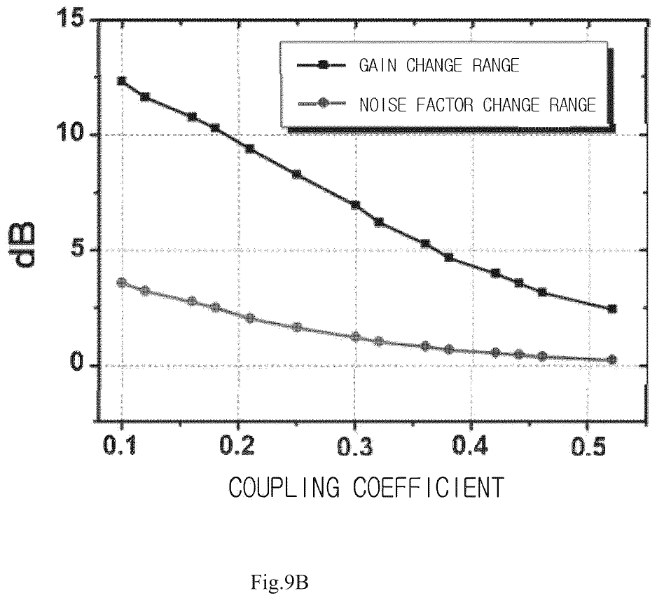

FIGS. 9A and 9B are graphs showing the results of simulating the voltage gain and noise factor according to changes in the value of k for the specific configuration of the noise-cancelling variable-gain amplifier according to an embodiment.

In particular, FIG. 9A shows changes in maximum and minimum gain and maximum and minimum noise factor NF according to the change in the value of the coupling coefficient k of the transformer TF1 designed in the circuit of FIG. 8, while FIG. 9B shows the range of changes in gain and noise characteristics according to the change in the value of the coupling coefficient k of the transformer TF1 in the circuit of FIG. 8.

As shown in the above Equations 4 and 9, it can be seen that the change rate of gain and noise may be controlled by controlling the coupling coefficient k. The increase rate of the noise factor NF may also be controlled by selecting an appropriate k value.

Referring to FIGS. 9A and 9B, in the variable-gain amplifier circuit of FIG. 8, when the coupling coefficient k is 0.3, the change in noise factor NF may be reduced to about 2 dB. When the coupling coefficient k is greater than 0.4, the change in NF may be reduced to 1 dB or less. Therefore, it can be confirmed through simulation that noise characteristics are improved through the noise-canceling variable-gain amplifier 100 based on the load transformer according to one embodiment.

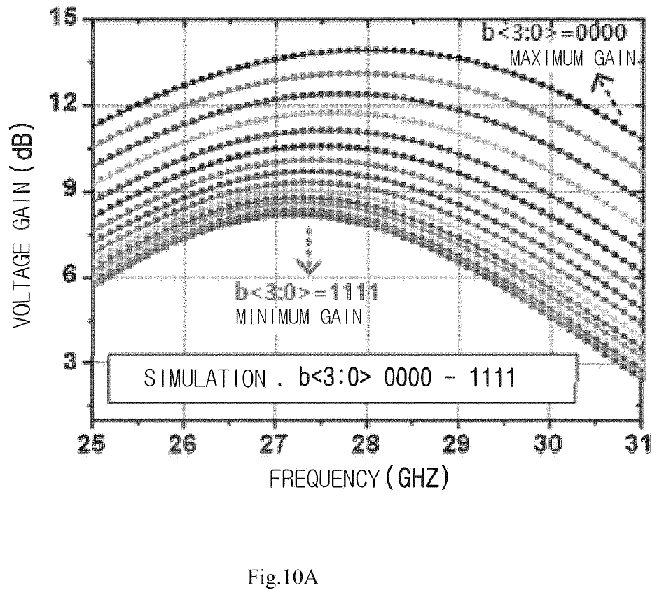

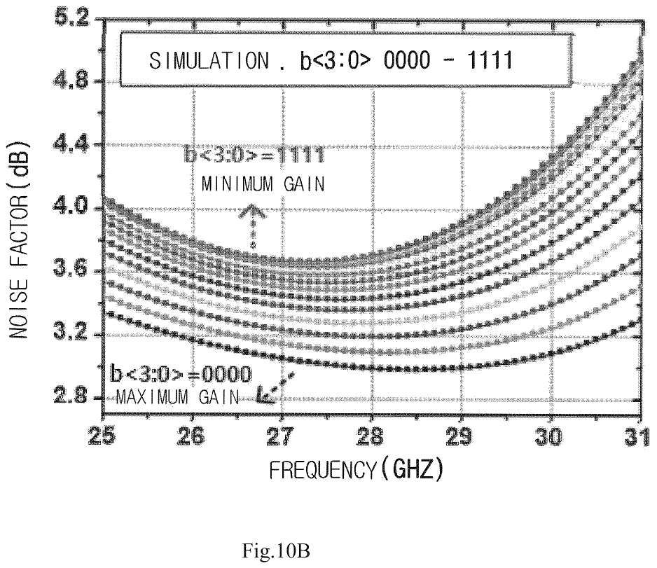

FIGS. 10A and 10B are graphs showing the results of simulating the gain and noise factor according to a change in frequency for the specific configuration of the noise-cancelling variable-gain amplifier according to an embodiment.

FIG. 10A shows the simulation result value of the variable-gain when the load transformer satisfying k=0.3 is applied to the circuit of FIG. 8. The uppermost black graph represents a case where all the gain control elements are turned off by sending “0000” to the control bit of the current steering part in FIG. 8, which allows the maximum gain to be obtained at each frequency. The lowermost red graph represents a case where all the gain control elements are turned on by sending “1111” to the control bit, which allows the minimum gain to be obtained at each frequency. In FIG. 10A, it can be confirmed that the frequency at which maximum gain is obtained is 28 GHz at the peak of the upper black graph (when all the gain control elements are turned off). At this time, the maximum gain is 13.9 dB in the black graph, and the gain control range to the red graph is 6.1 dB. These values may be adjusted by changing the k value.

FIG. 10B shows the simulation result value of noise characteristics NF when the load transformer satisfying k=0.3 is applied to the circuit of FIG. 8. The uppermost red graph represents a case where all the gain control elements are turned on by sending “1111” to the control bit of the current steering part in FIG. 8, while the lowermost black graph represents a case where all the gain control elements are turned off by sending “0000” to the control bit. In FIG. 10B, the minimum NF value may be obtained at the peak near 28 GHz in the lower black graph (when all the gain control elements are turned off), which represents the maximum variable gain. At this time, the minimum NF is 3 dB in the black graph, and even when converted to the minimum gain of the red graph, the NF is 3.68 dB, so it can be confirmed that NF degradation shows a low increase rate of 0.68 dB.

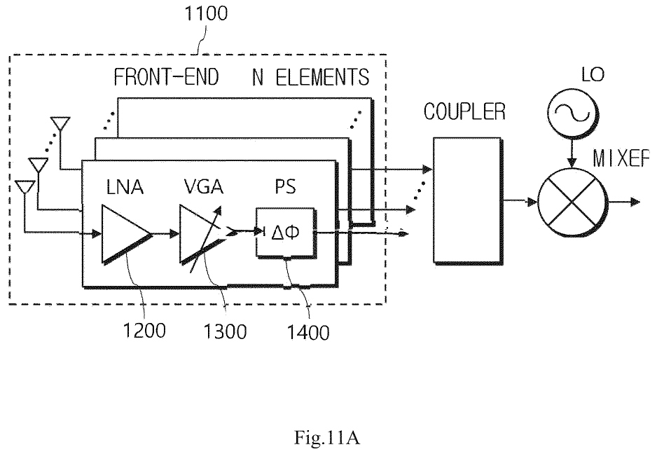

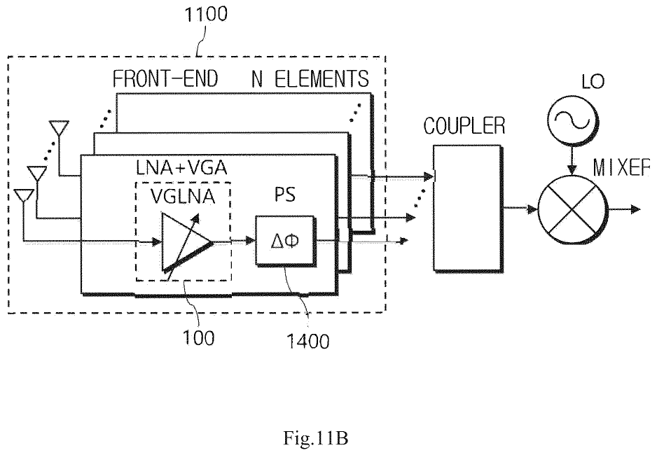

FIGS. 11A and 11B are schematic views showing the configuration of a front-end of a phased array receiver according to the prior art and a front-end of a phased array receiver using a noise-cancelling variable-gain amplifier according to an embodiment.

In particular, FIG. 11A shows the front-end according to the prior art, and FIG. 11B shows the front-end using the variable-gain amplifier according to an embodiment of the present disclosure.

Referring to FIG. 11A, the front-end 1100 of the phased array receiver according to the prior art includes a variable-gain amplifier (VGA) 1300, a low-noise amplifier (LNA) 1200, and a phase shifter (PS) 1300. A plurality of front-ends 1100 are provided and are used in transceiver phased array systems of various wireless communication systems including 3G, LTE, and 5G NR.

Referring to FIG. 11B, the low-noise variable-gain amplifier (VGLNA) 100 according to an embodiment of the present disclosure can effectively reduce noise even at low gain, so that it can perform the functions of the low-noise amplifier (LNA) and the variable-gain amplifier (VGA) according to the prior art. Consequently, it is possible to design a low-cost, high-efficiency transceiver.

The variable-gain amplifier 100 according to an embodiment of the present disclosure uses the MOSFET, and may be applied to all cascode structures using a current steering system. In addition, it is advantageous in that it is unnecessary to increase cost and size because it may be implemented by adding only the load transformer to the existing variable gain amplifier. By utilizing the characteristics of the variable gain amplifier that reduces the noise increase rate in the low gain mode, it is possible to perform the role of the low-noise amplifier, so it can be applied space- and cost-effectively to various MIMO and phased array systems such as 5G and beyond 5G.

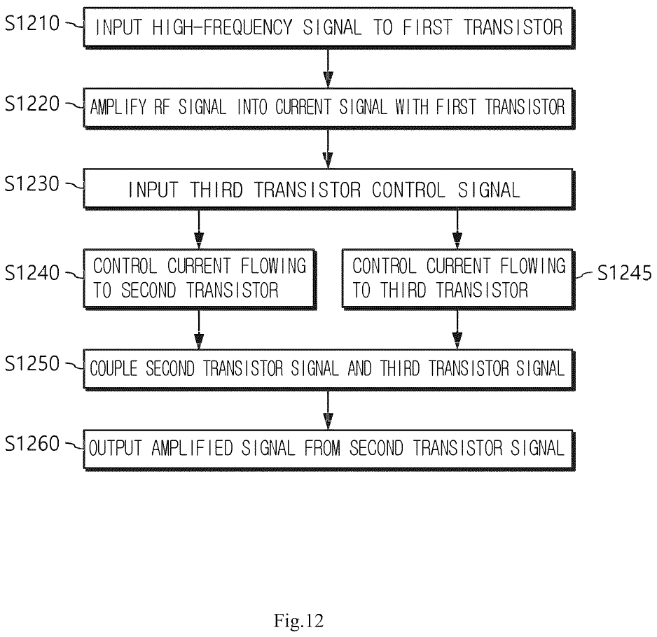

FIG. 12 is a flowchart schematically showing the operating method of a noise-cancelling variable-gain amplifier according to an embodiment.

Even if the above description is omitted in the operation of the variable-gain amplifier according to an embodiment in order to avoid redundancy, those skilled in the art can easily carry out the omitted part by referring to the above description.

Referring to FIG. 12, the operating method of the noise-cancelling variable-gain amplifier according to an embodiment includes a step of inputting a high-frequency signal to a signal input terminal of the first transistor (S1210). Further, using the first transistor, the input high-frequency RF signal is amplified into a current signal (S1220).

The second transistor is cascode-connected to the first transistor, and the third transistor is cascode-connected to the first transistor in parallel with the second transistor at the contact point where the first transistor and the second transistor are connected to each other. When the control signal for controlling the third transistor is input (S1230), the third transistor is operated in response to the input control signal. When the number α of third transistors operating according to the control signal is changed, the gain and the noise factor (NF) may be changed.

When the third transistor operates, the current flowing to the second transistor is controlled (S1240), and the current flowing to the third transistor is also controlled (S1245). As a result, the gain of the input high-frequency signal changes.

Meanwhile, the high-frequency signal flowing through the second transistor and the high-frequency signal flowing through the third transistor are coupled to each other through the load coupling part (S1250). The amplified and coupled signal is output from the second transistor (S1260).

According to an additional aspect, in the step S1250 of coupling the high-frequency signals, a coupling amount is determined by the coupling coefficient k between the primary coil of the transformer connected to the second transistor and the secondary coil of the transformer connected to the third transistor. When the coupling coefficient k changes, the coupling amount changes, which changes the gain and noise factor (NF).

According to an additional aspect, the operating method of the variable-gain amplifier further includes a step in which a signal flowing out of the primary coil and a signal flowing into the secondary coil via the third transistor are coupled to cancel each other out, with respect to the noise signal generated in the second transistor. At this time, since the signal flowing out of the primary coil and the signal flowing into the secondary coil are coupled in opposite phases, noise components in the output signal may be canceled out. As described in the previous FIG. 5, the noise voltage coupled to the output may be obtained using the current flowing out of the primary coil and the current flowing into the secondary coil, as in Equation 5. In Equation 7, the noise voltage coupled to the output decreases as the coupling coefficient k increases.

According to an additional aspect, the operating method of the variable-gain amplifier further includes a step in which a signal flowing into the primary coil via the second transistor and a signal flowing into the secondary coil are coupled to cancel each other out, with respect to the noise signal generated in the third transistor. As described in the previous FIG. 6, the noise voltage coupled to the output can be obtained using the current flowing into the primary coil and the current flowing into the secondary coil, as in Equation 7. In Equation 7, the noise voltage coupled to the output decreases as the coupling coefficient k increases.

Although the present disclosure has been described above with reference to preferred embodiments with reference to the accompanying drawings, it is not limited thereto and should be construed to encompass various modifications that can be obviously derived therefrom by those skilled in the art. The claims are intended to encompass these modifications.

### DESCRIPTION OF REFERENCE NUMERALS

100: variable-gain amplifier 100

110: main amplification part 110

130: current steering part 130

150: load coupling part 150

1. A noise-cancelling variable-gain amplifier comprising:
a main amplification part including a first transistor in which a high-frequency signal is input to a signal input terminal, and a second transistor cascode-connected to the first transistor, thereby amplifying and outputting an input high-frequency signal;
a current steering part including a third transistor cascode-connected to the first transistor in parallel with the second transistor at a contact point where the first transistor and the second transistor are connected to each other, thereby controlling a gain of the main amplification part; and
a load coupling part connected to the main amplification part and the current steering part, respectively, to couple a high-frequency signal of the main amplification part and a high-frequency signal of the current steering part.

2. The variable-gain amplifier of claim 1, wherein the load coupling part comprises:
a transformer configured so that a primary coil is connected between a power supply voltage and the main amplification part, and a secondary coil is connected between the power supply voltage and the current steering part.

3. The variable-gain amplifier of claim 1, wherein the load coupling part comprises:
a first inductor connected between the second transistor and the power supply voltage; and
a second inductor connected between the third transistor and the power supply voltage, and
the first inductor is magnetically coupled to the second inductor.

4. The variable-gain amplifier of claim 3, wherein the load coupling part further comprises:
a capacitor connected in parallel with the first inductor between the second transistor and the power supply voltage.

5. The variable-gain amplifier of claim 1, wherein the third transistor comprises:
a plurality of transistors connected in parallel with each other, each of the transistors being turned on or off in response to a control signal.

6. A method of operating a noise-cancelling variable-gain amplifier, the method comprising the steps of:
inputting a high-frequency signal to a signal input terminal of a first transistor;
amplifying the input high-frequency RF signal to a current signal, using the first transistor;
operating a third transistor cascode-connected to the first transistor in parallel with a second transistor at a contact point where the cascode-connected first transistor and second transistor are connected to each other, in response to a control signal;
coupling a high-frequency signal flowing through the second transistor and a high-frequency signal flowing through the third transistor; and
outputting an amplified signal from the second transistor.

7. The method of claim 6, further comprising:
a step of controlling a current flowing through the second transistor according to operation of the third transistor.

8. The method of claim 6, wherein in the step of coupling the high-frequency signals, a coupling amount is determined by a coupling coefficient between a primary coil of a transformer connected to the second transistor and a secondary coil of the transformer connected to the third transistor.

9. The method of claim 8, further comprising:
a step in which a signal flowing out of the primary coil and a signal flowing into the secondary coil via the third transistor are coupled to each other and canceled out, for a noise signal generated from the second transistor.

10. The method of claim 8, further comprising:
a step in which a signal flowing into the primary coil via the second transistor and a signal flowing into the secondary coil are coupled to each other and canceled out, for a noise signal generated from the third transistor.
